(19) United States
(12) Patent Application Publication
(10) Pub. No.: US 2015/0182023 A1
(43) Pub. Date: Jul. 2, 2015

(54) SLIDE ASSEMBLY FOR SERVER

(71) Applicants: HONG FU JIN PRECISION INDUSTRY (ShenZhen) CO., LTD, Shenzhen (CN); HON HAI PRECISION INDUSTRY CO., LTD., New Taipei (TW)

(72) Inventors: CHEN-LU FAN, New Taipei (TW); LI-PING CHEN, New Taipei (TW); CHANG-GUI CHEN, Shenzhen (CN)

(21) Appl. No.: 14/518,888

(22) Filed: Oct. 20, 2014

(30) Foreign Application Priority Data
Dec. 26, 2013 (CN) 201310729573.3

(51) Int. Cl. A47B 88/04; H05K 7/18

(52) U.S. Cl. CPC A47B 88/0418; H05K 7/183

(57) ABSTRACT

Slide assembly includes a frame, a first slide, a second slide and a clipping member. The frame includes a retaining panel. A securing panel is coupled to the retaining panel and secured to the retaining panel. The second slide is slidably attached to the first slide. The clipping member is attached to the second slide and extends out of the second slide. The clipping member is engaged with the retaining panel for preventing the second slide from moving relative to first slide.

### FIELD

The subject matter herein generally relates to a slide assembly.

### BACKGROUND

A slide assembly is used to a drawer with a cupboard or a server with a rack, movable relative to each other. Generally, a sliding assembly comprises an inner sliding member, a middle sliding member, and an outer sliding member. The outer sliding member is secured to a bracket of the rack, the inner sliding member is secured to a side surface of the server, and the middle sliding member is connected between the inner sliding member and the outer sliding member. The middle sliding member adds to the range of movement of the server. The middle sliding member and the inner sliding member are slidable relative to the outer sliding portion, and the server is slidable relative to the rack by the sliding assembly.

### BRIEF DESCRIPTION OF THE DRAWINGS

Implementations of the present technology will now be described, by way of example only, with reference to the attached figures.

FIG. 1 is an exploded, isometric view of an embodiment of a slide assembly.

FIG. 2 is a partly exploded view of the slide assembly of FIG. 1, but without a frame.

FIG. 3 is an assembly view of the slide assembly of FIG. 2.

FIG. 4 is an assembly view of the slide assembly of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein.

However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is described in relation to a slide assembly. The slide assembly includes a frame, a first slide, a second slide and a clipping member. The frame comprises a retaining panel. A securing panel is coupled to the retaining panel and secured to the retaining panel. The second slide is slidably attached to the first slide. The clipping member is attached to the second slide and extends out of the second slide. The clipping member is engaged with the retaining panel for prevent the second slide from first slide.

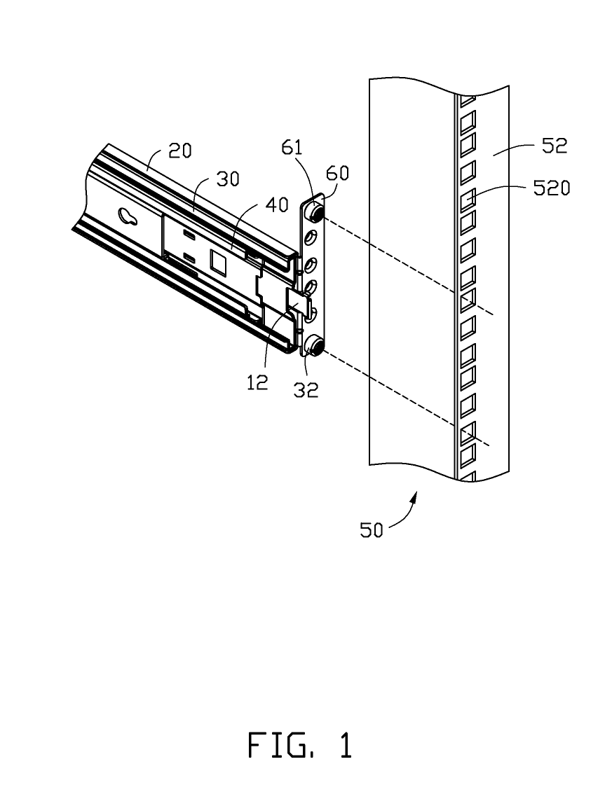

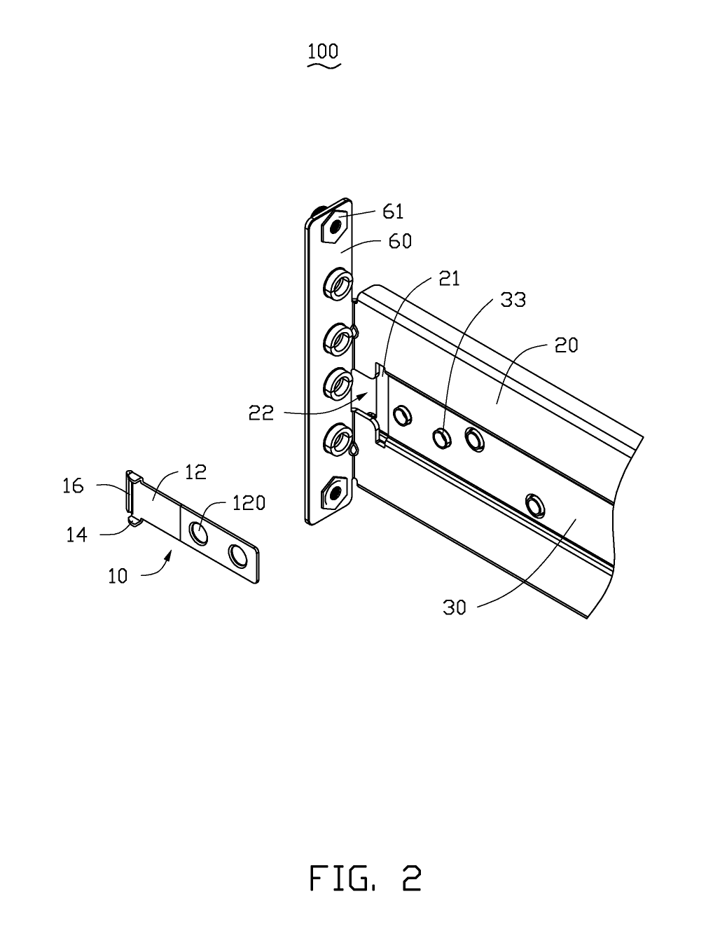

FIGS. 1-2 illustrate an embodiment of a slide assembly. The slide assembly comprises a clipping member 10, a first slide 20, a second slide 30, a third slide 40, and a frame 50 of a server (not shown). The second slide 30 is located between the first slide 20 and the third slide 40 and can be slidable relative to the first slide 20.

The clipping member 10 can be secured to the second slide 20 and comprises a main body 12, two clipping portions 14 and an operating portion 16. The main body 12 defines two fixing holes 120. In at least one embodiment, each clipping portion 14 is a clipping piece that is substantially perpendicular to the main body 12, and the operating portion 16 is curved.

The first slide 20 defines a through hole 21 and a coupling hole 22. The through hole 21 is configured for exposing the second slide 30. A securing panel 60 is coupled to the first slide 20. In at least one embodiment, the securing panel 60 is substantially perpendicular to the first slide 20. Two securing posts 61 are located on the securing panel 60.

The second slide 30 is exposed by the through hole 21 and two mounting posts 33 are located on the second slide 30. The two mounting posts 33 can be engaged in the two fixing holes 120 to mount the clipping member 10 to the second slide 30.

The frame 50 comprises a retaining panel 52. The retaining panel 52 defines a plurality of retaining holes 520.

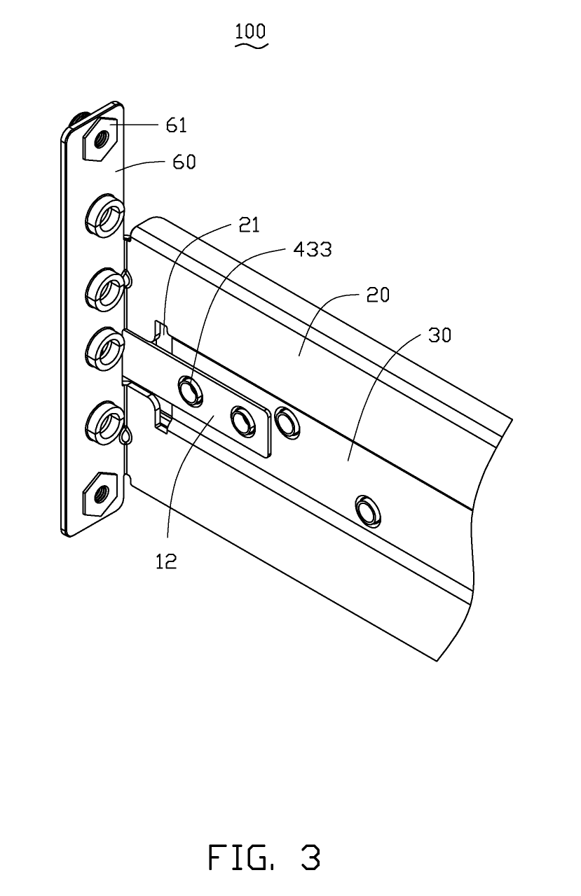

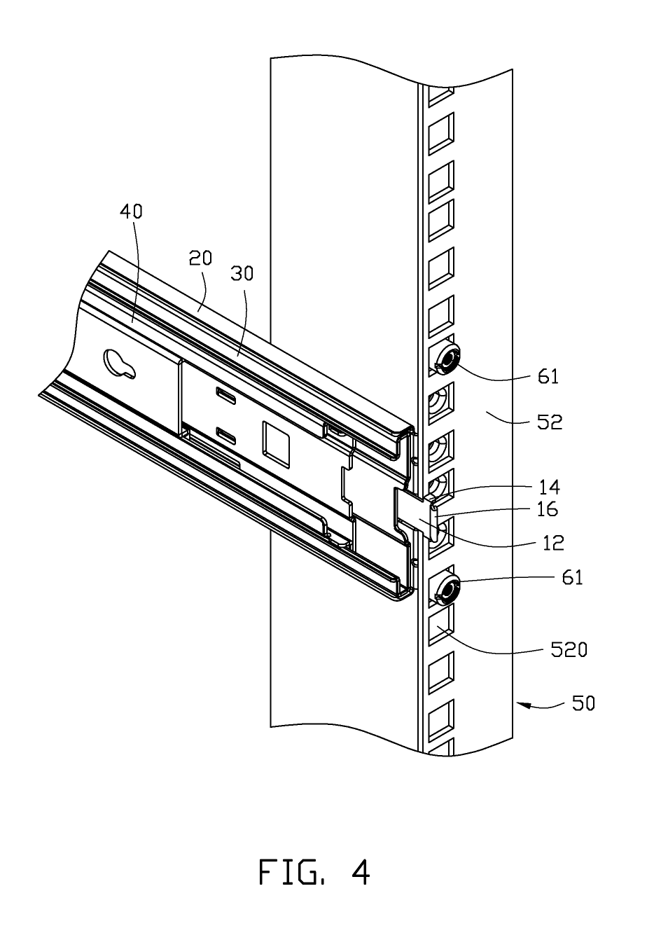

FIGS. 3-4 illustrates an assembly of the slide assembly. The clipping member 10 abuts the second slide 30, and the two mounting posts 33 are engaged in the two fixing holes 120 to mount the clipping member 10 to the second slide 30. The main body 12 extends through the coupling hole 22 to be located outside of the securing panel 60.

The securing panel 60 abuts the retaining panel 52, and the two securing posts 61 are engaged in the two retaining holes 520 to secure the securing panel 60 to the frame 50. The second slide 30 is slid relative to the first slide 20 in a first direction towards the retaining panel 52, until the two clipping portions 14 are engaged with the retaining panel 52. Therefore, the second slide 30 cannot be slid in a second opposite direction with the clipping portions 14 engaging with the retaining panel 52.

When the second slide 30 needs to be slid relative to the first slide 20, the operating portion 16 is operated to disengage the clipping portions 14 from the retaining panel 52. Therefore, the second slide 30 can be slid relative to the first slide 20.

The embodiments shown and described above are only examples. Many details are often found in the art such as the other features of a frame. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A slide assembly comprising:
a frame comprising a retaining panel;
a first slide;
a securing panel coupled to the retaining panel and secured to the retaining panel;
a second slide slidably attached to the first slide ; and
a clipping member attached to the second slide and extending out of the second slide;
wherein the clipping member is engaged with the retaining panel for preventing the second slide from moving relative to first slide.

2. The slide assembly of claim 1, wherein the clipping member comprises a main body and a clipping portion located on the main body, and the main body extends out of the second slide and the clipping portion is engaged with the retaining panel.

3. The slide assembly of claim 2, wherein the clipping portion is substantially perpendicular to the main body.

4. The slide assembly of claim 2, wherein the clipping member further comprises an operating portion located on the main body, and the operating portion is configured to disengage the clipping portion from the retaining panel.

5. The slide assembly of claim 4, wherein the operating portion is curved.

6. The slide assembly of claim 1, wherein the first slide defines a through hole, and the second slide is exposed by the through hole and comprises a mounting post, and the clipping member is secured to the mounting post.

7. The slide assembly of claim 6, wherein the first slide defines a coupling hole communicating with the through hole, and the clipping member extends through the coupling hole to expose out of the second slide.

8. The slide assembly of claim 1, wherein the securing panel is substantially perpendicular to the first slide.

9. The slide assembly of claim 1, wherein the retaining panel defines a retaining hole, and the securing panel comprises a securing post engaged in the retaining hole.

10. A slide assembly comprising:
a frame comprising a retaining panel;
a first slide defining a through hole; a securing panel coupled to the retaining panel and secured to the retaining panel;
a second slide slidably attached to the first slide and exposed by the through hole ;
and a clipping member attached to the second slide and extending out of the second slide;
the clipping member comprises a clipping portion;
wherein the clipping portion is engaged with the retaining panel for preventing the second slide from moving relative to the first slide.

11. The slide assembly of claim 10, wherein the clipping member comprises a main body, the clipping portion is located on the main body.

12. The slide assembly of claim 11, wherein the clipping portion is substantially perpendicular to the main body.

13. The slide assembly of claim 11, wherein the clipping member further comprises an operating portion located on the main body, and the operating portion is configured to disengage the clipping portion from the retaining panel.

14. The slide assembly of claim 13, wherein the operating portion is curved.

15. The slide assembly of claim 10, wherein the second slide comprises a mounting post, and the clipping member defines a fixing hole, and the mounting post is engaged in the fixing hole to secure the clipping member to the second slide.

16. The slide assembly of claim 10, wherein the first slide defines a coupling hole communicating with the through hole, and the clipping member extends through the coupling hole to expose out of the second slide.

17. The slide assembly of claim 10, wherein the securing panel is substantially perpendicular to the first slide.

18. The slide assembly of claim 10, wherein the retaining panel defines a retaining hole, and the securing panel comprises a securing post engaged in the retaining hole.
